(19) United States
(12) Patent Application Publication
(10) Pub. No.: US 2019/0330755 A1
(43) Pub. Date: Oct. 31, 2019

(54) ALUMINUM ALLOY CASING, PREPARATION METHOD THEREOF, AND PERSONAL ELECTRONIC DEVICE

(71) Applicant: BYD COMPANY LIMITED, Shenzhen (CN)

(72) Inventors: Chongchong LIAO, Shenzhen (CN); Yu WANG, Shenzhen (CN); Liang CHEN, Shenzhen (CN); Xiong XIONG, Shenzhen (CN)

(21) Appl. No.: 16/475,311

(22) PCT Filed: Dec. 6, 2017
(86) PCT No.: PCT/CN2017/114854

§ 371 Date: Jul. 1, 2019

(30) Foreign Application Priority Data
Dec. 30, 2016 (CN) 201611265161.9

(51) Int. Cl. C25D 11/08; C25D 11/12; C25D 11/16; C25D 11/22; H05K 5/04; C25D 9/04

(52) U.S. Cl. CPC C25D 11/08; C25D 11/12; C25D 9/04; C25D 11/22; H05K 5/04; C25D 11/16

(57) ABSTRACT

The present disclosure provides an aluminum alloy casing, a preparation method thereof, and a personal electronic device. The aluminum alloy casing includes an aluminum alloy matrix and an oxide film layer covering the surface of the aluminum alloy matrix, wherein the aluminum alloy matrix has a slit, the oxide film layer includes an inner anodic oxide film layer and an outer anodic oxide film layer, and the inner anodic oxide film layer has inner anodic oxide film layer nanopores; and the outer anodic oxide film layer has outer anodic oxide film layer nanopores.

### FIELD

The present invention relates to the field of material chemistry and, in particular, to an aluminum alloy casing, a preparation method thereof, and a personal electronic device.

### BACKGROUND

A mobile phone antenna is a device for receiving signals on a mobile phone. Currently, smartphones on the market mostly have built-in antennas, which requires that a back cover of the phone cannot shield the signals. The absorption of electromagnetic waves by metals is very strong, so that when WiFi, 2G, and 3G signals are sent into metal materials, absorption attenuation occurs, and electromagnetic waves cannot reach a signal receiving module, resulting in signal shielding. Therefore, for a metal body mobile phone, how to solve the signal shielding problem is one of the keys to its design and manufacture. At present, the signal shielding problem of metal bodies of the mobile phones is usually solved by using antenna slotting and injection molding methods, such as upper and lower antenna slots of HTC ONE, and side antenna slots of iPhone 5/5s. Although this can prevent signal shielding, it causes certain damage to the overall structure of a metal body, affecting the cleanliness and continuity of the appearance of the metal body. At the same time, the plastic visible in the outer casing destroys the overall metal texture of the body.

### SUMMARY

An objective of the present invention is to provide an aluminum alloy casing, a preparation method thereof, and a personal electronic device. An antenna slot of the aluminum alloy casing is apparently invisible.

To achieve the above objective, in a first aspect of the present invention, the present invention provides an aluminum alloy casing, including an aluminum alloy matrix and oxide film layer covering the surface of the aluminum alloy matrix. The aluminum alloy matrix has a slit, the slit is provided with an outer opening on an outer surface and an inner opening on a an inner surface of the aluminum alloy matrix, the oxide film layer closes the outer opening of the slit, the oxide film layer includes an inner anodic oxide film layer and an outer anodic oxide film layer, the inner anodic oxide film layer has inner anodic oxide film layer nanopores, the inner anodic oxide film layer nanopores have a pore size of 30 nm to 100 nm, the outer anodic oxide film layer has outer anodic oxide film layer nanopores, the outer anodic oxide film layer nanopores have a pore size of 10 nm to 50 nm, and the pore size of the inner anodic oxide film layer nanopores is greater than the pore size of the outer anodic oxide film layer nanopores.

Through the above technical solution, the aluminum alloy casing provided by the present invention is a continuous metal layer as seen from the outer surface of the casing, and the slit in the metal layer can be used as an antenna slot. The oxide film layer on the surface of the metal layer has a good shielding effect, so that the slit is apparently invisible, and the casing is clean and smooth and has a good metal texture. In addition, the higher hardness of the oxide film layer gives the aluminum alloy casing excellent wear resistance, shock resistance and corrosion resistance.

The additional aspects and advantages of the present invention will be provided in the following description, and some of the additional aspects and advantages will become clear in the following description or be understood through practice of the present invention.

### BRIEF DESCRIPTION OF THE DRAWINGS

The accompanying drawings are used to provide a further understanding of the present invention, and constitute a part of the specification, which are used to explain the present invention in combination with the following specific implementations, and do not constitute a limitation to the present invention. In the accompanying drawings:

FIG. 1 is a structural view of a specific implementation of an aluminum alloy casing provided by the present disclosure;

FIG. 2 is a scanning electron micrograph of the cross section of an interface between an inner anodic oxide film layer and an outer anodic oxide film layer of an aluminum alloy casing prepared in an embodiment of the present disclosure;

FIG. 3 is a scanning electron micrograph of the cross section of an outer anodic oxide film layer of an aluminum alloy casing prepared in an embodiment of the present disclosure;

FIG. 4 is a scanning electron micrograph of the cross section of an inner anodic oxide film layer of an aluminum alloy casing prepared in an embodiment of the present disclosure;

FIG. 5 is a scanning electron micrograph of the surface of an outer anodic oxide film layer of an aluminum alloy casing prepared in an embodiment of the present disclosure; and

FIG. 6 is a scanning electron micrograph of the bottom of an inner anodic oxide film layer of an aluminum alloy casing prepared in an embodiment of the present disclosure.

### DESCRIPTION OF THE REFERENCE NUMERALS

1 Aluminum alloy matrix 2 Oxide film layer 21 Inner anodic oxide film layer
22 Outer anodic oxide film layer 3 Slit 4 Outer opening
5 Inner opening

### DETAILED DESCRIPTION

The following describes in detail embodiments of the present disclosure. Examples of the embodiments are shown in the accompanying drawings, where reference signs that are the same or similar from beginning to end represent same or similar components or components that have same or similar functions. The following embodiments described with reference to the accompanying drawings are exemplary, and are intended to describe the present disclosure and cannot be construed as a limitation to the present disclosure.

In the description of the present disclosure, it should be understood that, orientations or position relationships indicated by terms such as “center”, “longitudinal”, “transverse”, “length”, “width”, “thickness”, “up”, “down”, “front”, “back”, “left”, “right”, “vertical”, “horizontal”, “top”, “bottom”, “inner”, “outer”, “clockwise”, “counterclockwise”, “axial”, “radial”, and “circumferential” are orientations or position relationship shown based on the accompanying drawings, and are merely used for describing the present disclosure and simplifying the description, rather than indicating or implying that the apparatus or element should have a particular orientation or be constructed and operated in a particular orientation, and therefore, should not be construed as a limitation on the present disclosure.

In addition, terms “first” and “second” are used only for description purposes, and shall not be understood as indicating or suggesting relative importance or implicitly indicating a quantity of indicated technical features. Therefore, features defined by “first” and “second” may explicitly or implicitly include at least one feature. In the description of the present disclosure, unless otherwise specifically limited, “multiple” means at least two, for example, two or three.

In the present disclosure, it should be noted that unless otherwise clearly specified and limited, the terms “mounted”, “connected”, “connection”, and “fixed” should be understood in a broad sense. For example, a connection may be a fixed connection, a detachable connection, or an integral connection; may be a mechanical connection or an electrical connection; may be a direct connection or an indirect connection by means of an intermediate medium; or may be internal communication between two elements or interaction relationship between two elements, unless otherwise clearly limited. A person of ordinary skill in the art may understand specific meanings of the terms in the present disclosure according to specific situations.

In the present disclosure, unless otherwise clearly specified and limited, that a first feature is “above” or “below” a second feature may be that the first and the second features are in contact with each other directly, or the first and the second features are in contact with each other indirectly by using an intermediate medium. Moreover, that the first feature is “above”, “over”, and “on” the second feature may be that the first feature is right above the second feature or at an inclined top of the second feature, or may merely indicate that the horizontal height of the first feature is higher than that of the second feature. That the first feature is “below”, “under”, and “beneath” the second feature may be that the first feature is right below the second feature or at an inclined bottom of the second feature, or may merely indicate that the horizontal height of the first feature is lower than that of the second feature.

The present disclosure provides an aluminum alloy casing, including an aluminum alloy matrix 1 and an oxide film layer 2 covering the surface of the aluminum alloy matrix 1. The aluminum alloy matrix 1 comprises a slit 3, and the slit 3 is provided with an outer opening 4 on an outer surface and an inner opening 5 on an inner surface of the aluminum alloy matrix 1, and the oxide film layer 2 seals the outer opening 4 of the slit. The aluminum alloy casing of the present disclosure can be used for a back casing of a personal electronic communication device such as a mobile phone, and the slit can be used as an antenna slot without a signal shielding phenomenon. In the present disclosure, in the case of no indication to the contrary, the “outer surface” of the aluminum alloy matrix refers to a side away from a device body when used in a back casing of a personal electronic communication device such as a mobile phone, and the “inner surface” refers to a side close to the device body.

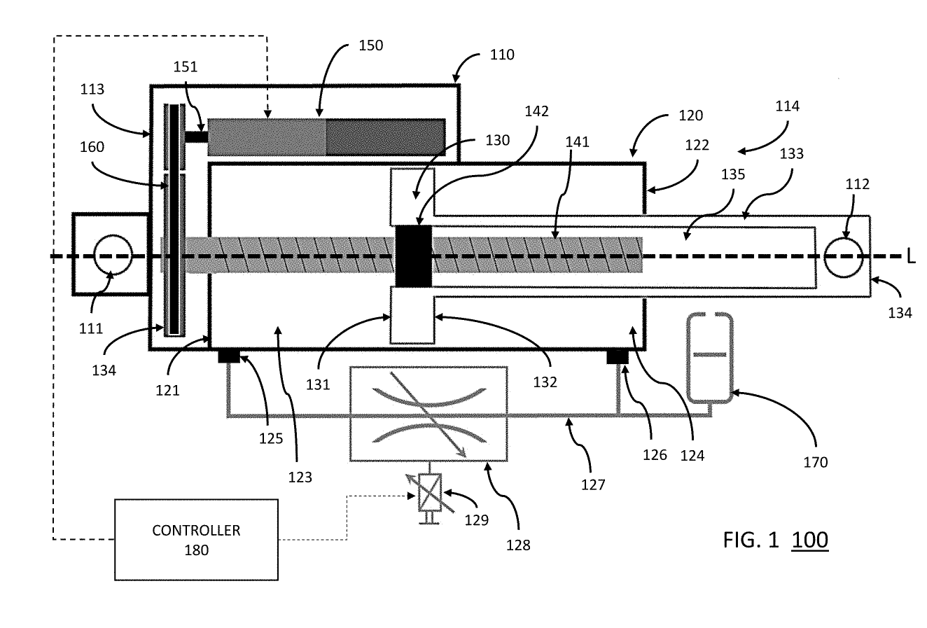

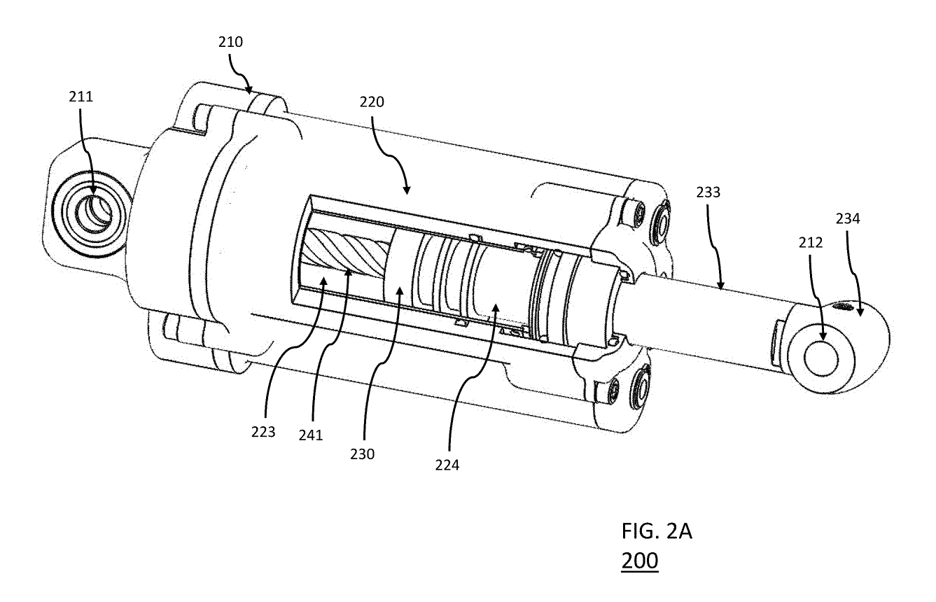

According to the present disclosure, the oxide film layer 2 may include at least one inner anodic oxide film layer 21 and at least one outer anodic oxide film layer 22. FIG. 1 is a structural view of a specific implementation of an aluminum alloy casing provided by the first aspect of the present disclosure. As shown in FIG. 1, the oxide film layer 2 includes an inner anodic oxide film layer 21 and an outer anodic oxide film layer 22.

According to the present disclosure, the inner anodic oxide film layer 21 comprises inner anodic oxide film layer nanopores, and the inner anodic oxide film layer nanopores may have a pore size of 30 nm to 100 nm. The outer anodic oxide film layer 22 comprises outer anodic oxide film layer nanopores, the outer anodic oxide film layer nanopores may have a pore size of 10 nm to 50 nm, and the pore size of the inner anodic oxide film layer nanopores is greater than the pore size of the outer anodic oxide film layer nanopores. The density of nanopores of the inner anodic oxide film layer is 550 pores/μm² to 900 pores/μm², and the density of nanopores of the outer anodic oxide film layer is 200 pores/μm² to 550 pores/μm². The pore size of the nanopores in the oxide film layer may be measured by a JSM-7600F thermal field scanning electron microscope. The surface of the anodic oxide film not subjected to pore sealing is photographed and observed at a magnification of 100000 times, and the average pore diameter of the nanopores per unit area is calculated as the pore size of the nanopores in the oxide film layer. The density of the nanopores may be measured by a JSM-7600F thermal field scanning electron microscope. The surface of the oxide film not subjected to pore sealing is photographed and observed at a magnification of 20000 to 100000 times, and the number of the nanopores or nanotubes per unit area is calculated as the density of the nanopores.

According to present disclosure, to make the oxide film layer have shielding properties and reduce its light transmittance such that the slit is apparently invisible, the inner anodic oxide film layer nanopores and the outer anodic oxide film layer nanopores may be each independently filled with an electrolytic coloring dye and/or a dyeing dye. The electrolytic coloring dye may include an inorganic dye, and the dyeing dye may include an organic dye. Further, the inorganic dye may be an inorganic dye obtained by performing an electrolytic coloring treatment on an aqueous solution containing sulfuric acid and a non-ferrous metal salt, and the non-ferrous metal salt may include at least one of tin sulfate, nickel sulfate and silver sulfate. The organic dye may include at least one of Okuno 420 dye, 415 dye, and 419 dye. The inner anodic oxide film layer nanopores and the outer anodic oxide film layer nanopores are filled with an electrolytic coloring dye and/or a dyeing dye, wherein the lightness L in the CIE-stipulated Lab display system of the oxide film layer (2) is 0 to 30, the chromaticity A in the CIE-stipulated Lab display system of the oxide film layer (2) is 0 to 2, the chromaticity B in the CIE-stipulated Lab display system of the oxide film layer (2) is 0 to 2, and a dyeing depth of the oxide film layer (2) is greater than 10 μm. Wherein meanings of the lightness L, he chromaticity A, the chromaticity B are well known to those skilled in the art. The lightness L refers to a depth of a color. The darker the color, the smaller the L value, and the lighter the color, the larger the L value. The chromaticity A refers to an absolute value of red and green phase values measured by a color difference meter. When the A value is positive, it represents red, and when the A value is negative, it represents green. The chromaticity B refers to an absolute value of yellow and blue phase values measured by the color difference meter. When the B value is positive, it represents yellow, and when the B value is negative, it represents blue. In the present disclosure, the lightness L, chromaticity A and chromaticity B are measured by using an ICS-90 ion chromatograph of DIONEX CHINA LIMITED. The dyeing depth refers to a thickness of the film layer from the surface of the oxide film to the underlying nanopores in which the dye is in saturation or near saturation.

The aluminum alloy casing provided by the present disclosure has a higher hardness, and the oxide film layer 2 may have a hardness of 320 HV_{0.1} to 500 HV_{0.1}, such that the wear resistance, shock resistance and corrosion resistance are better. The hardness of the oxide film layer may be measured by directly measuring the surface hardness of the oxide film by using an HV-100 instrument of Shanghai Aolong Xingdi Testing Instrument Co., Ltd. The test conditions are: a pressure of 1 N, and a holding time of 10 s.

According to the present disclosure, the inner anodic oxide film layer 21 may have a thickness of 1 μm, to 60 μm, preferably 10 μm, to 20 μm. The outer anodic oxide film layer 22 may have a thickness of 1 μm, to 60 μm, preferably 10 μm, to 20 μm.

According to the present disclosure, the width of the slit 3 may be any width suitable as an antenna slot, for example, may be 0.5 mm to 10 mm, preferably 1 to 3 mm. The number and position of the slits 3 can be designed according to actual needs. For example, the number of the slits 3 may be 1 to 10, preferably 1 to 3. The presence of the slit 3 may separate the aluminum alloy matrix 1 into at least two pieces insulated from each other. The presence of the slit 3 may also partially separate the aluminum alloy matrix 1, and the separated aluminum alloy matrix 1 may also be a unitary piece. To ensure that the antenna in the personal electronic communication device can receive signals and ensure the continuity of the aluminum alloy casing, the slit 3 may be filled with an insulator, and the type of the insulator may be conventionally used in the art, and may be, for example, a colloidal material or the like.

The aluminum alloy casing provided by the first aspect of the present disclosure is a continuous metal layer as seen from the outer surface of the casing, and the slit in the metal layer is filled with an insulator and can be used as an antenna slot. The oxide film layer on the surface of the metal layer is filled with at least one of an electrolytic coloring dye and a dyeing dye, and since the pore size of the inner anodic oxide film layer nanopores is greater than that of the outer anodic oxide film layer nanopores, more electrolytic coloring dye and/or the dyeing dye are deposited on the inner anodic oxide film layer more easily. The oxide film layer has a certain color depth, and thus, has a good shielding effect, so that the slit is apparently invisible, and the casing is clean and smooth and has a good metal texture. In addition, the higher hardness of the oxide film layer gives the aluminum alloy casing excellent wear resistance, shock resistance and corrosion resistance.

The present disclosure provides a method for preparing an aluminum alloy casing, including the following steps: a. performing anodic oxidation treatments on the aluminum alloy matrix to obtain an aluminum alloy matrix covered with an oxide film layer, where the anodic oxidation treatments include a first anodic oxidation treatment and a second anodic oxidation treatment, the first anodic oxidation treatment causes an outer anodic oxide film layer containing nanopores having a pore size of 10 nm to 50 nm to be formed on the aluminum alloy matrix, and the second anodic oxidation treatment causes an inner anodic oxide film layer containing nanopores having a pore size of 30 nm to 100 nm to be formed on the aluminum alloy matrix; and b. partially removing the aluminum alloy matrix portion of the aluminum alloy matrix covered with the oxide film layer obtained in step a to form a slit, where the slit is separately provided with an outer opening and an inner opening on an outer surface and an inner surface of the aluminum alloy matrix, and the oxide film layer closes the outer opening of the slit. Two different anodic oxidation treatments on the aluminum alloy matrix can form an oxide film layer having nanopores with different pore sizes on the surface of the aluminum alloy matrix. Wherein the density of the nanopores of the inner anodic oxide film layer is 550 pores/μm² to 900 pores/μm², and the density of the nanopores of the outer anodic oxide film layer is 200 pores/μm² to 550 pores/μm².

According to the present disclosure, before performing the anodic oxidation treatment on the aluminum alloy matrix, pretreatment may be performed. The pretreatment is well known to those skilled in the art and may include, for example, steps such as degreasing, alkali etching, neutralization, chemical polishing, and water washing.

According to the present disclosure, the first anodic oxidation treatment may include contacting the aluminum alloy matrix with a first aqueous solution containing sulfuric acid and oxalic acid. Based on 1000 parts by weight of the first aqueous solution, a content of the sulfuric acid may be 90 to 260 parts by weight, preferably 160 to 190 parts by weight, and a content of the oxalic acid may be 4 to 25 parts by weight, preferably 6 to 10 parts by weight. The first anodic oxidation treatment is performed under a pulse current, and conditions of the first anodic oxidation treatment may be as follows: a pulse waveform of the current is a forward square wave pulse, a duty cycle is 30 to 99%, a frequency of the current is 100 to 1000 Hz, a current density is 2 to 8 A/dm², a voltage is 30 to 60 V, a temperature is 0 to 20° C., and a time is 10 to 80 min. In actual operation, the aluminum alloy matrix may be placed in an anodizing bath containing the first aqueous solution for the first anodic oxidation treatment under the above conditions.

According to the present disclosure, the second anodic oxidation treatment may include contacting the aluminum alloy matrix with a second aqueous solution containing sulfuric acid. Based on 1000 parts by weight of the second aqueous solution, a content of the sulfuric acid may be 110 to 360 parts by weight, preferably 180 to 200 parts by weight. The second anodic oxidation treatment is performed under a direct current, and conditions of the second anodic oxidation treatment may be as follows: a voltage of 13 to 20 V, a temperature of 5 to 25° C., and a time of 5 to 60 min. In actual operation, after the first anodic oxidation treatment, the aluminum alloy matrix can be quickly transferred to an anodizing bath containing the second aqueous solution for the second anodic oxidation treatment, and the hardness of the oxide film layer formed on the surface of the aluminum alloy matrix is 320 HV_{0.1} to 500 HV_{0.1}.

According to the present disclosure, the number of times of the first anodic oxidation treatment and the second anodic oxidation treatment is not particularly limited. For example, one or more first anodic oxidation treatments and one or more second anodic oxidation treatments may be performed as long as the first treatment is the first anodic oxidation treatment is performed for the first time and the last treatment is the second anodic oxidation treatment in the anodic oxidation treatment process. Steps of anodic oxidation treatments may be added therebetween as many times as needed. The first anodic oxidation treatment and the second anodic oxidation treatment may be sequentially performed, or the second anodic oxidation treatment and the first anodic oxidation treatment may be sequentially performed, or they may be alternately performed repeatedly.

According to the present disclosure, to make the oxide film layer have opacity such that the slit is apparently invisible, the method may further include: sequentially performing an electrolytic coloring treatment and a dyeing treatment on the aluminum alloy matrix covered with the oxide film layer obtained in step a, and then performing the operation of step b. The electrolytic coloring treatment and the dyeing treatment make the oxide film layer has a lightness L in the CIE-stipulated Lab display system of 0 to 30, a chromaticity A in the CIE-stipulated Lab display system of 0 to 2, a chromaticity B in the CIE-stipulated Lab display system of 0 to 2, and a dyeing depth of more than 10 μm.

According to the present disclosure, the electrolytic coloring treatment may include: contacting the aluminum alloy matrix covered with the oxide film layer with an electrolyte. The electrolyte may be an aqueous solution containing sulfuric acid and a non-ferrous metal salt. A ratio of the sulfuric acid to the metal salt may be any suitable ratio, preferably, based on 1000 parts by weight of the electrolyte, the content of the sulfuric acid is 10 to 20 parts by weight, and the content of the metal salt is 5 to 30 parts by weight. The non-ferrous metal salt may include at least one of tin sulfate, nickel sulfate, and silver sulfate, and the non-ferrous metal salt is preferably a metal salt of a dark color such as black. Conditions of the electrolytic coloring treatment may be as follows: a voltage of 15 V to 20 V, a temperature of 20° C. to 30° C., and a time of 10 min to 20 min. The electrolytic coloring treatment can preferentially deposit the electrolytic coloring dye on the inner anodic oxide film layer, and the dye gradually transits to the outer anodic oxide film layer as an electrolytic coloring treatment time is extended. After the electrolytic coloring treatment, the aluminum alloy matrix may be washed with deionized water.

According to the present disclosure, the aluminum alloy matrix may be subjected to a dyeing treatment after the electrolytic coloring treatment. The dyeing treatment may include: contacting the aluminum alloy matrix covered with the oxide film layer with an organic dye. The organic dye may include at least one of Okuno 420 dye, 415 dye, and 419 dye. A concentration of the organic dye may be any suitable ratio, and preferably, the concentration of the organic dye is 10 to 20 g/L. Conditions of the dyeing treatment may be as follows: a temperature is 40 to 60° C., and a time is 20 to 40 min. The dyeing treatment causes the nanopores of the oxide film layer to be filled with a dyeing dye.

According to the present disclosure, in order to enhance the pollution resistance and corrosion resistance of the oxide film layer, the method may further include: after sequentially performing an electrolytic coloring treatment and a dyeing treatment on the aluminum alloy matrix covered with the oxide film layer obtained in step a, performing pore sealing, and then performing the operation of step b. The pore sealing method is well known to those skilled in the art and may, for example, be high-temperature pore sealing or cold pore sealing. The high-temperature pore sealing may be performed by placing the aluminum alloy matrix covered with the oxide film layer in water at a temperature of 90 to 95° C. for 15 to 20 min. The cold pore sealing may be performed by contacting, at a room temperature, the aluminum alloy matrix covered with the oxide film layer with a pore sealing solution containing nickel fluoride or the like. The pore sealing is preferably high-temperature pore sealing.

According to the present disclosure, those skilled in the art can understand that, in the step of anodic oxidation treatment, since the outer surface and the inner surface of the aluminum alloy matrix are both covered with an oxide film layer, to form the slit of the aluminum alloy matrix, in step b, the outer surface and a portion of the inner side surface of the aluminum alloy matrix covered with the oxide film layer may be firstly covered with a protective layer, and then the portion of the oxide film layer and the aluminum alloy matrix which are not covered with the protective layer are removed. That is, the removed portion is the oxide film layer on the portion of the inner surface and the aluminum alloy matrix which are not covered with the protective layer of the aluminum alloy matrix, so that the slit is formed. The protective layer is a material that is physically or chemically covered on the surface of the aluminum alloy matrix such that the portion of the oxide film layer and the aluminum alloy matrix which are covered with the protective layer are not damaged, and may be, for example, an ink coating layer or a silica gel film layer. The ink may be of a conventional type on the market, and may be, for example, a UV ink. The silica gel film is also commercially available, and may be, for example, a GHT2545G green silica gel protective film purchased from Shenzhen Ximengte Electronics Co., Ltd. After covering the protective layer, the oxide film on the surface of the aluminum alloy matrix and the aluminum alloy matrix which are not covered with the protective layer may be removed by a method including, but not limited to, laser engraving removal, CNC machine tool removal and chemical etching removal. The operation steps and conditions of the laser engraving, the CNC, and chemical etching may all be used conventionally in the art. For example, the conditions of the laser engraving may be as follows: the power is 70 to 110, the laser running speed is 1980 to 2020 mm/s, and the frequency is 10 to 50 kHz. The chemical etching may include: contacting the aluminum alloy matrix with an etching solution containing ferric trichloride and hydrochloric acid. Based on 100 parts by weight of the etching solution, the content of the ferric trichloride is 70 to 90 parts by weight, the content of the hydrochloric acid is 4 to 8 parts by weight, and the content of water is 10 to 15 parts by weight. The temperature of the chemical etching may be 20 to 35° C., and the time may be 10 to 30 minutes. The oxide film layer and a portion of the aluminum alloy matrix can be removed by means of the laser engraving and the CNC machine tool, and all the aluminum alloy matrix can be further removed by means of the chemical etching.

According to the present disclosure, after the portion of the oxide film layer and the aluminum alloy matrix which are not covered with the protective layer are removed, the method further includes a step of filling the slit with an insulator. The type of the insulator may be conventionally used in the art, and may be, for example, a colloidal material or the like. To further make the slit apparently invisible, the color of the colloidal material is preferably another color that is non-transparent. Solid particles may also be added to the colloidal material to produce a reflective effect to further enhance the invisibility of the slit. The solid particles may include a metal element or a metal oxide, the metal element may be silver and/or aluminum, and the metal oxide may be titanium dioxide and/or aluminum oxide.

According to the present disclosure, after the slit is filled with the colloid, the aluminum alloy casing has been substantially prepared, and only the removal of the protective layer is required. If the protective layer is an ink coating layer, the method for removing the protective layer may be performed by soaking the aluminum alloy casing by using a paint stripper which can dissolve the ink coating layer but does not react with the oxide film layer, the aluminum alloy matrix and the insulator in the slit. The paint stripper is commercially available, and may be, for example, an SH-665 paint stripper purchased from Dongguan Sihui Surface Processing Technology Co., Ltd.

The present disclosure provides an aluminum alloy casing which, according to an embodiment of the present disclosure, is prepared by the method of the second aspect of the present disclosure.

The present disclosure provides a personal electronic device, which includes the aluminum alloy casing according to the first aspect or the third aspect of the present disclosure.

The present disclosure is further illustrated by the following Embodiments, without thereby limiting content of the present disclosure.

In the embodiment, the morphology of the oxide film layer, the pore size of the nanopores in the oxide film layer, and the density of the nanopores were measured by a JSM-7600F scanning electron microscope manufactured by JEOL, and the magnification was 100000 times.

### Embodiment 1

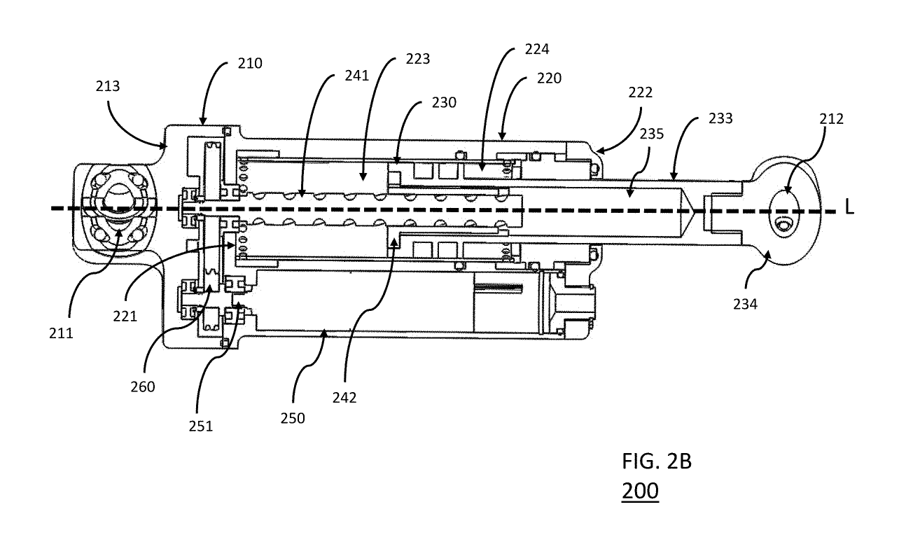

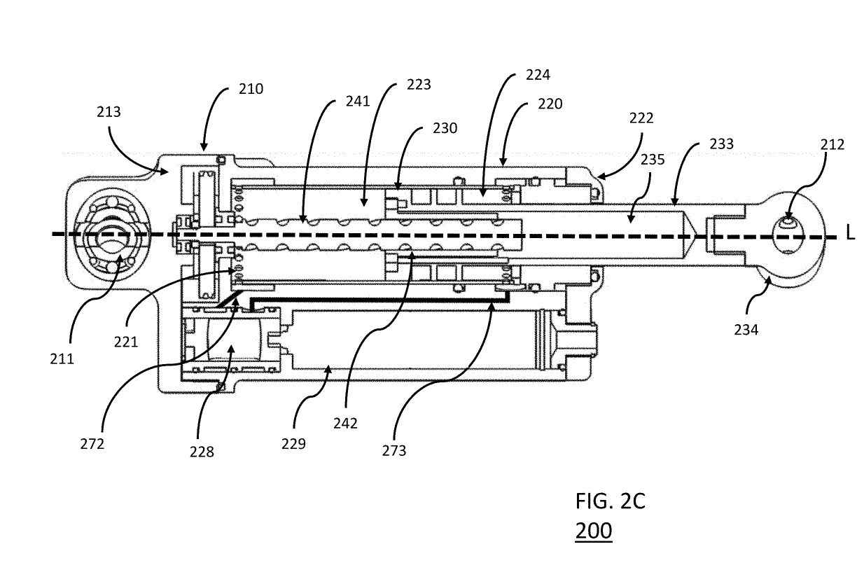

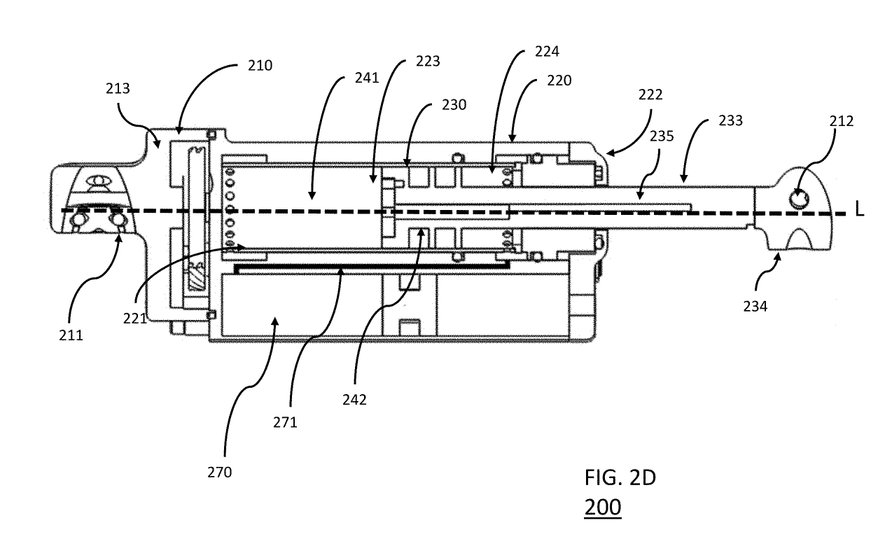

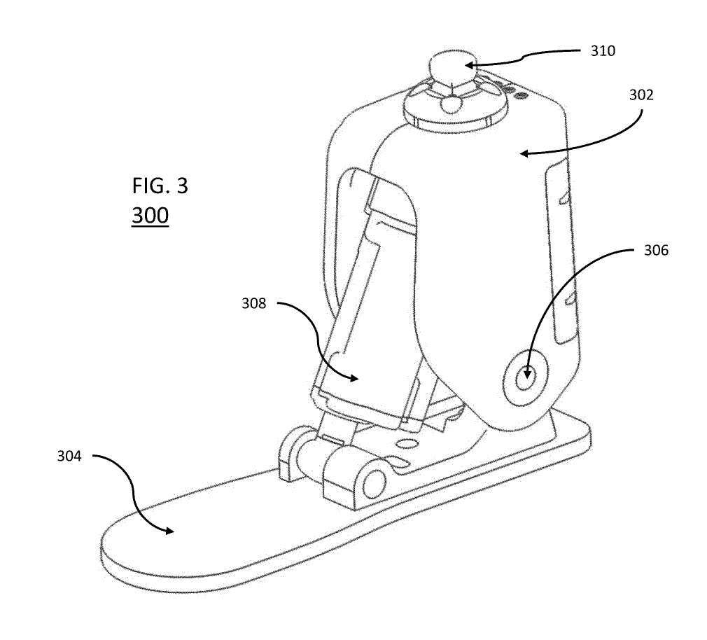

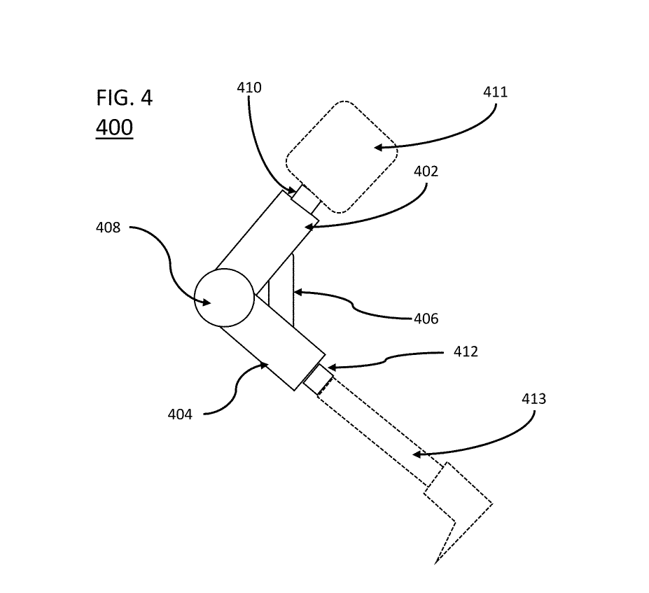

The aluminum alloy matrix was pretreated, including alkali etching, neutralization, chemical polishing, water washing and the like. Then, the pretreated aluminum alloy matrix was placed in an anodizing bath containing an aqueous solution containing sulfuric acid and oxalic acid for a first anodic oxidation treatment. Based on 1000 parts by weight of the aqueous solution, a content of the sulfuric acid was 180 parts by weight, and a content of the oxalic acid was 8 parts by weight. Conditions were as follows: a pulse waveform of a current was a forward square wave pulse, a duty cycle was 80%, a frequency of the current was 800 Hz, a current density was 4 A/dm², a temperature was 10° C., and a time was 25 min. An outer anodic oxide film layer having a thickness of 15 μm was obtained. Nanopores of the outer anodic oxide film layer had a pore size of 25 nm, and nanopores of the outer anodic oxide film layer had a density of 386 pores/square micrometer. After the first anodic oxidation treatment was completed, the aluminum alloy matrix and a hanger were quickly transferred to an anodizing bath containing an aqueous solution containing sulfuric acid for a second anodic oxidation treatment. Based on 1000 parts by weight of the aqueous solution, the content of the sulfuric acid was 190 parts by weight. Conditions were as follows: a voltage was 15 V, a temperature was 19° C., and a time was 35 min. Thus, an inner anodic oxide film layer having a thickness of 15 μm was formed between the outer anodic oxide film layer and the aluminum alloy matrix. Nanopores of the inner anodic oxide film layer had a pore size of 30 nm, and nanopores of the inner anodic oxide film layer had a density of 770 pores/square micrometer. After the second anodic oxidation treatment, the aluminum alloy matrix was washed with deionized water and transferred to an electrolytic coloring tank for electrolytic coloring treatment. The composition and content of the electrolyte were as follows: based on 1000 parts by weight of the electrolyte, a content of stannous sulfate was 8 parts by weight, a content of sulfuric acid was 17 parts by weight, and a content of nickel sulfate hexahydrate was 20 parts by weight. Conditions of the electrolytic coloring treatment were as follows: a temperature was 25° C., a voltage was 20 V, and a time was 10 min. Then, the aluminum alloy matrix was washed with deionized water. The elemental composition of the aluminum alloy matrix after the electrolytic coloring treatment was as follows: 14.32 wt % of O, 68.11 wt % o of Al, 5.96 wt % of S, 8.95 wt % of Sn, and 2.66 wt % of Ni in content. Then, the aluminum alloy matrix was placed in an organic dye tank for dyeing treatment. A dye was Okuno 420 dye, a concentration was 20 g/L, and conditions of the dyeing treatment were as follows: a temperature was 40° C., and a time was 10 min. Then, the aluminum alloy matrix was placed in water at 95° C. for high-temperature pore sealing for 20 min. The outer surface and a portion of the inner surface of the aluminum alloy matrix were covered with a silica gel protective film (a GHT2545G green silica gel protective film purchased from Shenzhen Ximengte Electronics Co., Ltd.) to form a protective layer, and the uncovered portion was subjected to laser engraving to remove the portion of the oxide film layer and a portion of the aluminum alloy matrix in the following conditions: a power was 70%, a laser running speed was 3000 mm/s, and a frequency was 80 KHz. Then, the aluminum alloy matrix was placed in a container containing an etching solution for chemical etching. The composition and content of the etching solution were as follows: based on 100 parts by weight of the etching solution, a content of ferric trichloride was 80 parts by weight, a content of hydrochloric acid was 8 parts by weight, and a content of water was 12 parts by weight. An etching temperature was a normal temperature, and an etching time was 10 minutes. After the chemical etching, the aluminum alloy matrix in the region not covered with the protective layer was completely removed to form one slit, and a width of the slit was 2 mm. The slit was filled with a white colloidal material. Finally, the silica gel protective film layer was removed to obtain the aluminum alloy casing provided by this embodiment. The scanning electron micrograph of the cross section of the oxide film layer of the aluminum alloy casing prepared in this embodiment is shown in FIG. 2. It can be seen that the oxide film layer has a distinct composite film interface of the inner anodic oxide film layer and the outer anodic oxide film layer. The scanning electron micrographs of the cross section of the outer anodic oxide film layer and the cross section of the inner anodic oxide film layer are shown in FIG. 3 and FIG. 4. It can be seen that the inner anodic oxide film layer has nanopores having a larger pore size. The scanning electron micrographs of the surface of the outer anodic oxide film layer and the bottom of the inner anodic oxide film layer are shown in FIG. 5 and FIG. 6.

### Preparation Embodiment 1

A difference from the Embodiment is that in this preparation embodiment, the step of electrolytic coloring treatment was not performed.

### Preparation Embodiment 2

A difference from the Embodiment is that in this preparation embodiment, the step of dyeing treatment was not performed.

### Comparative Embodiment 1

A difference from the Embodiment is that in this comparative embodiment, the step of a second anodic oxidation treatment was not performed, and the time of the first anodic oxidation treatment was increased to 50 min.

### Comparative Embodiment 2

A difference from the Embodiment is that in this comparative embodiment, the step of the first anodic oxidation treatment was not performed, and the time of the second anodic oxidation treatment was increased to 70 min.

### Test Embodiment

The dyeing depth, color depth L value, color A value, color B value, hardness, and appearance effect of the aluminum alloy casing of the Embodiment and Comparative Embodiments 1 and 2 were tested. The results are shown in Table 1.

The test method of the dyeing depth was: a difference of the color of the cross section of the anodic oxide film was observed by using an Axio Imsger Alm metallographic microscope of Zeiss Optical Instrument International Trading Co., Ltd., so as to determine the dyeing depth. The dyeing depth refers to a thickness of the film layer from the surface of the oxide film to the underlying nanopores in which the dye is in saturation or near saturation.

The test method of the color depth L value, color A value and color B value was: the measurement was performed by directly measuring the surface by using an ICS-90 ion chromatograph of DIONEX CHINA LIMITED.

The test method of the hardness was: the measurement was performed by directly measuring the surface hardness of the oxide film by using an HV-100 instrument of Shanghai Aolong Xingdi Testing Instrument Co., Ltd. Test conditions were: a pressure 1 N, and a holding time 10 s.

The test method of the appearance effect was: the prepared aluminum alloy casing was photographed, colors of the antenna slot portion and other portions of the aluminum alloy casing in the photograph were respectively picked, a color of the antenna slot portion was recorded as color 1 (R₁, G₁, B₁), a color of the other portions was recorded as color 2 (R₂, G₂, B₂), and an average value V of the color component deviation of color 1 and color 2 was calculated according to Equation (I). When V was between 0.8 and 1.2, the difference in film color between the antenna slot portion and the other portions was difficult to distinguish with a naked eye. That is, the antenna slot was invisible, and otherwise the antenna slot was visible.

$$V = ( \frac{{R}_{2} - {R}_{1}}{{R}_{1}} + \frac{{G}_{2} - {G}_{1}}{{G}_{1}} + \frac{{B}_{2} - {B}_{1}}{{B}_{1}} ) \div 3 \qquad Equation ( I )$$

Then, the prepared aluminum alloy casing was placed on a horizontal surface, and the surface of the aluminum alloy casing was irradiated with light of 45° with the horizontal surface, a photograph was taken, and photoshop software was used to find whether there were shadows or bright spots on the surface of the aluminum alloy casing. When the oxide film layer of the antenna slot portion of the aluminum alloy casing had defects such as bumps or pits, the bumps or pits irradiated by light formed shadows or bright spots, and otherwise, there were no shadows or bright spots.

TABLE 1

| | Dyeing | Color Depth | Color A | Color B | Hardness/ | Appearance |
|---|---|---|---|---|---|---|
| | Depth/μm | L Value | Value | Value | HV_{0.1} | Effect |
| Embodiment 1 | 11.31 | 28.63 | 0.08 | −0.97 | 336.04 | The antenna slot |
| | | | | | | is invisible, and |
| | | | | | | the film layer is |
| | | | | | | not deformed |
| Comparative | 7.88 | 28.16 | 0.71 | −0.02 | 413.11 | The antenna slot |
| Embodiment 1 | | | | | | is visible, and the |
| | | | | | | film layer is not |
| | | | | | | deformed |
| Comparative | 12.2 | 27.25 | −0.26 | −1.64 | 317.61 | The antenna slot |
| Embodiment 2 | | | | | | is invisible, and |
| | | | | | | the film layer is |
| | | | | | | deformed |

It can be seen that the aluminum alloy casing provided by the present disclosure is a continuous metal layer as seen from the outer surface of the casing, and the oxide film layer on the surface of the metal layer has a good shielding effect, so that the slit is apparently invisible, and the casing is clean and smooth and has a good metal texture. In addition, the higher hardness of the oxide film layer gives the aluminum alloy casing excellent wear resistance, shock resistance and corrosion resistance.

Although preferred implementations of the present disclosure have been described in detail above with reference to the accompanying drawings, the present disclosure is not limited to specific details in the foregoing implementations. Various simple variations can be made to the technical solutions of the present disclosure within the scope of the technical idea of the present disclosure, and such simple variations all fall within the protection scope of the present disclosure.

In addition, it should be noted that, the specific technical features described in the foregoing specific implementations may be combined in any suitable manner when there is no contradiction. To avoid unnecessary repetition, various possible combination manners are not additionally described in the present disclosure.

In addition, any combination may be made between various different implementations of the present disclosure, and the combination shall also be regarded as content disclosed by the present disclosure provided that it does not depart from the idea of the present disclosure.

In the description of the specification, the description made with reference to terms such as “one embodiment”, “some embodiments”, “example”, “specific example”, or “some examples” means that a specific characteristic, structure, material or feature described with reference to the embodiment or example is included in at least one embodiment or example of the present disclosure. In this specification, schematic descriptions of the foregoing terms do not need to aim at a same embodiment or example. Besides, the specific features, the structures, the materials or the characteristics that are described may be combined in a proper manner in any one or more embodiments or examples. In addition, in a case that is not mutually contradictory, persons skilled in the art can combine or group different embodiments or examples that are described in this specification and features of the different embodiments or examples.

Although the embodiments of the present disclosure are shown and described above, it can be understood that, the foregoing embodiments are exemplary, and cannot be construed as a limitation to the present disclosure. Within the scope of the present disclosure, a person of ordinary skill in the art may make changes, modifications, replacement, and variations to the foregoing embodiments.

1. An aluminum alloy casing, comprising:
an aluminum alloy matrix, and
an oxide film layer covering the surface of the aluminum alloy matrix,
wherein the aluminum alloy matrix comprises a slit, and
the slit is provided with an outer opening on an outer surface and an inner opening on an inner surface of the aluminum alloy matrix, wherein
the oxide film layer seals the outer opening of the slit, and
the oxide film layer comprises an inner anodic oxide film layer and an outer anodic oxide film layer, and
the inner anodic oxide film layer comprises inner anodic oxide film layer nanopores, wherein
the inner anodic oxide film layer nanopores have a pore size of 30 nm to 100 nm, and
the outer anodic oxide film layer comprises outer anodic oxide film layer nanopores, wherein
the outer anodic oxide film layer nanopores have a pore size of 10 nm to 50 nm, and
the pore size of the inner anodic oxide film layer nanopores is greater than the pore size of the outer anodic oxide film layer nanopores.

2. The aluminum alloy casing according to claim 1, wherein the density of nanopores of the inner anodic oxide film layer is 550 pores/μm² to 900 pores/μm², and the density of nanopores of the outer anodic oxide film layer is 200 pores/μm² to 550 pores/μm².

3. The aluminum alloy casing according to claim 1, wherein the inner anodic oxide film layer nanopores and the outer anodic oxide film layer nanopores are each independently filled with at least one of an electrolytic coloring dye and a dyeing dye, wherein the electrolytic coloring dye comprises an inorganic dye, and the dyeing dye comprising an organic dye.

4. The aluminum alloy casing according to claim 1, wherein the inorganic dye is obtained by performing an electrolytic coloring treatment on an aqueous solution containing sulfuric acid and a non-ferrous metal salt, and the non-ferrous metal salt comprises at least one of tin sulfate, nickel sulfate and silver sulfate; and
the organic dye comprises at least one of Okuno 420 dye, 415 dye and 419 dye.

5. The aluminum alloy casing according to claim 1, wherein the lightness L in the CIE-stipulated Lab display system of the oxide film layer is 0 to 30, the chromaticity A in the CIE-stipulated Lab display system of the oxide film layer is 0 to 2, the chromaticity B in the CIE-stipulated Lab display system of the oxide film layer is 0 to 2, and a dyeing depth of the oxide film layer is greater than 10 μm.

6. The aluminum alloy casing according to claim 1, wherein the oxide film layer has a hardness of 320 HV0.1 to 500 HV0.1.

7. The aluminum alloy casing according to claim 1, wherein the inner anodic oxide film layer has a thickness of 1 to 60 μm; and
the outer anodic oxide film layer has a thickness of 1 to 60 μm.

8. The aluminum alloy casing according to claim 1, wherein the slit has a width of 0.5 to 10 mm, and the number of the slits is 1 to 10.

9. The aluminum alloy casing according to claim 1, wherein the slit separates the aluminum alloy matrix into at least two pieces insulated from each other.

10. The aluminum alloy casing according to claim 1, wherein the slit is filled with an insulator.

11. A method for preparing an aluminum alloy casing, comprising:
a. performing anodic oxidation treatments on the aluminum alloy matrix to obtain an aluminum alloy matrix covered with an oxide film layer, wherein the anodic oxidation treatments comprise a first anodic oxidation treatment and a second anodic oxidation treatment, the first anodic oxidation treatment causes an outer anodic oxide film layer containing nanopores having a pore size of 10 to 50 nm to be formed on the aluminum alloy matrix, and the second anodic oxidation treatment causes an inner anodic oxide film layer containing nanopores having a pore size of 30 to 100 nm to be formed on the aluminum alloy matrix; and
b. partially removing the aluminum alloy matrix portion of the aluminum alloy matrix covered with the oxide film layer obtained in step a to form a slit, wherein the slit is separately provided with an outer opening and an inner opening on an outer surface and an inner surface of the aluminum alloy matrix, and the oxide film layer closes the outer opening of the slit.

12. The method according to claim 11, wherein the density of nanopores of the inner anodic oxide film layer is 550 pores/μm² to 900 pores/μm², and the density of nanopores of the outer anodic oxide film layer is 200 pores/μm² to 550 pores/μm².

13. The method according to claim 11, wherein the first anodic oxidation treatment comprises contacting the aluminum alloy matrix with a first aqueous solution containing sulfuric acid and oxalic acid, wherein based on the first aqueous solution, a content of the sulfuric acid is 9% to 26% by weight, and a content of the oxalic acid is 0.4% to 0.25% by weight; and
the second anodic oxidation treatment comprises contacting the aluminum alloy matrix with a second aqueous solution containing sulfuric acid, wherein based on the second aqueous solution, a content of the sulfuric acid is 11% to 36% by weight,
wherein the first anodic oxidation treatment is performed under a pulse current, and conditions of the first anodic oxidation treatment are as follows: a pulse waveform of the current is a forward square wave pulse, a duty cycle of 30% to 99%, a frequency of the current of 100 Hz to 1000 Hz, a current density of 2 A/dm2 to 8 A/dm2, the voltage of 30 V to 60 V, a temperature of 0° C. to 20° C., and a time of 10 min to 80 min; and
the second anodic oxidation treatment is performed under a direct current, and conditions of the second anodic oxidation treatment are as follows: a voltage of 13 V to 20 V, a temperature of 5° C. to 25° C., and a time of 5 min to 60 min.

14. (canceled)

15. The method according to claim 11, wherein the method further comprises: sequentially performing an electrolytic coloring treatment and a dyeing treatment on the aluminum alloy matrix covered with the oxide film layer obtained in step a, and then performing the operation of step b.

16. The method according to claim 11, wherein the electrolytic coloring treatment and the dyeing treatment make the oxide film layer has a lightness L in the CIE-stipulated Lab display system of 0 to 30, a chromaticity A in the CIE-stipulated Lab display system of 0 to 2, a chromaticity B in the CIE-stipulated Lab display system of 0 to 2, and a dyeing depth of more than 10 μm.

17. The method according to claim 11, wherein the electrolytic coloring treatment comprises contacting the aluminum alloy matrix covered with the oxide film layer with an electrolyte, wherein the electrolyte is an aqueous solution containing sulfuric acid and a non-ferrous metal salt, and the non-ferrous metal salt comprises at least one of tin sulfate, nickel sulfate, and silver sulfate,
wherein conditions of the electrolytic coloring treatment are as follows: a voltage of 15 V to 20 V, a temperature of 20° C. to 30° C., and a time of 10 min to 20 min.

18. (canceled)

19. The method according to claim 11, wherein the dyeing treatment comprises contacting the aluminum alloy matrix covered with the oxide film layer with an organic dye, the organic dye comprising at least one of Okuno 420 dye, 415 dye and 419 dye,
wherein conditions of the dyeing treatment are as follows: a temperature of 40° C. to 60° C., and a time of 20 min to 40 min.

20. (canceled)

21. (canceled)

22. The method according to claim 14, wherein in step b, the outer surface and a portion of the inner surface of the aluminum alloy matrix covered with the oxide film layer are firstly covered with a protective layer, and the portion of the oxide film layer and the aluminum alloy matrix which are not covered with the protective layer are removed to form the slit, wherein the removal step comprises at least one of laser engraving removal step, CNC machine tool removal step, and chemical etching removal step.

23. The method according to claim 11, wherein the method further comprises a step of filling the slit with an insulator.

24. (canceled)

25. A personal electronic device, comprising the aluminum alloy casing according to claim 1.
